(19) United States
(12) Patent Application Publication
(10) Pub. No.: US 2004/0262638 A1
(43) Pub. Date: Dec. 30, 2004

(54) Integrated circuit with dram memory cell

(76) Inventors: Pascale Mazoyer, Domene (FR); Christian Caillat, Grenoble (FR)

Correspondence Address: FLEIT, KAIN, GIBBONS, GUTMAN, BONGINI, & BIANCO P.L., ONE BOCA COMMERCE CENTER, 551 NORTHWEST 77TH STREET, SUITE 111, BOCA RATON, FL, 33487, US

(21) Appl. No.: 10/486,752

(22) PCT Filed: Aug. 14, 2002
(86) PCT No.: PCT/FR02/02887

(30) Foreign Application Priority Data
Aug. 16, 2001 (FR) 01/10867

(51) Int. Cl. H01L 31/0336

(52) U.S. Cl. 257/201

(57) ABSTRACT

Integrated circuit with dram memory cell Integrated circuit comprising a substrate (1), at least one capacitor (9) placed above the substrate (1) and provided with a first electrode (5), with a second electrode (8) and with a dielectric (7) placed between the two electrodes, at least one via for connection between the substrate (1) and a conductor level lying above the capacitor (9), and a dielectric covering the substrate (1) and surrounding both the capacitor (9) and the via (6).

The via comprises a first portion (18) lying between the substrate and the lower level of the first electrode, a second portion (6) lying between the lower level of the first electrode and the upper level of the first electrode, and a third portion (12) in contact with the first portion and flush with the said conductor level, the second portion being made from the same material as the first electrode of the capacitor.

The present invention relates in general to integrated circuits, especially memory cells. More particularly, the present invention relates to memory cells of the dynamic random access (DRAM) type, which are compatible with a process for fabricating a device incorporating such a memory and CMOS components.

Conventionally, a DRAM memory is in the form of rows and columns at the intersections of which are memory cells consisting of a memory element, typically a capacitor, and of a switch for controlling this memory element, in general an MOS transistor.

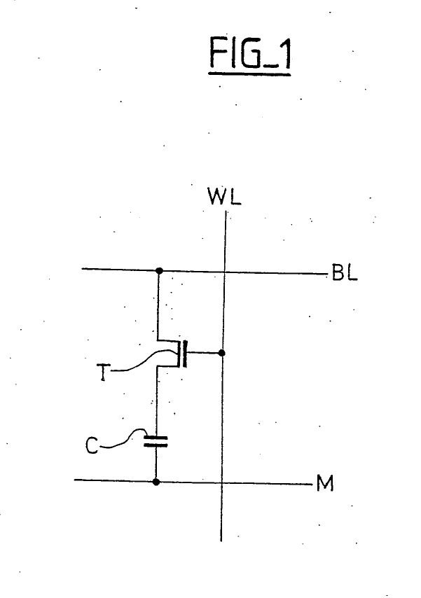

A DRAM-type memory cell (FIG. 1) consists of a control MOS transistor T and a storage capacitor C which are connected in series between an electrical earth M and a bit line BL. The gate of the control transistor T is connected to a word line WL. The transistor T controls the flow of electrical charges between the capacitor C and the bit line BL. The electrical charge on the capacitor C determines the logic level, 1 or 0, of the memory cell. When reading the memory location, the capacitor C discharges into the bit line BL. To read the value of the electrical charge on the storage capacitor C quickly and reliably, the capacitance of this capacitor must be high compared with the capacitance presented by the bit line BL during the reading phase.

A large number of DRAM cells formed in this way are grouped together in the form of a matrix so as to generate a memory plane which may comprise millions of elementary cells. For some applications, the memory plane lies within a complex integrated circuit. One therefore speaks of on-board memory.

The memory elements are structures based on capacitors comprising a first electrode of any shape, for example a U shape. The memory capacitors also include a very thin dielectric and a second electrode which is common to several capacitors and consists of a continuous conducting layer, for example made of polycrystalline silicon, placed above the said insulating layer.

One or more vias have to be provided for connection between one or more active regions formed in the substrate and a conducting level formed above the dielectric layer which covers the capacitor.

The term “via” is understood to mean, within the context of the present invention, a hole filled with an electrically conductive material capable of making an electrical connection between two or more levels of an integrated circuit.

Such a via may be formed by etching a hole through the combination of dielectric layers in which the capacitor is formed, so as to reach the substrate, and by filling this hole with a conductive material, for example tungsten. Such a hole has a very high height/width ratio and is therefore difficult to fill suitably with the metal intended to form the via. There is therefore a risk of obtaining a via whose electrical resistance value will be high and will exhibit substantial variations from one via to another.

The object of the invention is to remedy the abovementioned drawbacks.

The subject of the invention is an integrated circuit provided with a high-quality contact between an active region of a substrate and a conducting level lying above a capacitor.

According to one aspect of the invention, the integrated circuit comprises a substrate, at least one capacitor placed above the substrate and provided with a first electrode, with a second electrode and with a insulating layer placed between the two electrodes, at least one via for connection between the substrate and a conductor level lying above the capacitor, and a dielectric covering the substrate and surrounding both the capacitor and the via.

The via comprises a first portion lying between the substrate and the lower level of the first electrode, a second portion lying between the lower level of the first electrode and the upper level of the first electrode, and a third portion in contact with the first portion and flush with the said conductor level, the second portion being made from the same material as the first electrode of the capacitor.

The succession of technological steps to produce the capacitor may advantageously be used in producing the via. A distinction will be made between a first via portion, between the substrate and the bottom of the lower electrode, a second portion, between the bottom and the top of the lower electrode, and a third portion, between the top of the lower electrode and the conducting level.

The capacitor may be of the cavitied type with a U-shaped cross section.

In one embodiment of the invention, the material of which the first electrode of the capacitor and the second via portion are composed comprises polysilicon.

In another embodiment of the invention, the material of which the first electrode of the capacitor and the second via portion are composed comprises metal, especially a metal or a metal-based alloy comprising copper, aluminium, tungsten, gold and/or titanium.

In one embodiment of the invention, the said capacitor forms part of a memory cell. The first electrode may be connected to an active region of the substrate, for example to the drain or to the source of an MOS transistor. The other electrode may be connected to electrodes of other capacitors.

According to one aspect of the invention, the fabrication process is intended for an integrated circuit. Starting from a substrate covered with at least one dielectric layer, the following are formed: a first capacitor electrode placed above the substrate, a capacitor dielectric, a second capacitor electrode, with the dielectric placed between the two electrodes, and at least one via for connection between the substrate and a conducting level lying above the capacitor and a dielectric covering the substrate and surrounding both the capacitor and the via, the via comprising a first portion lying between the substrate and the lower level of the first electrode, a second portion between the lower level and the upper level of the first electrode, and a third portion in contact with the second portion and flush with the said conducting level, the second portion and the first electrode being formed simultaneously and from the same material.

More particularly starting from a substrate covered with at least one dielectric layer, a first hole and a second hole are simultaneously etched away and filled with a first electrically conductive material. A dielectric layer is deposited. The dielectric layer is etched away to produce at least one cavity for the purpose of forming a capacitor and at least one third hole for the purpose of forming a via. A layer of a second conductive material is deposited on the upper surface of the dielectric layer, the said second material filling the said third hole and coating the bottom walls of the said cavity. The said second conductive material is removed from the upper surface of the dielectric layer, remaining in the hole and in the cavity. At least one thin layer of dielectric is deposited at least on the surface of the conducting layer in the cavity. The second electrode is formed by depositing a second layer of the second conductive material in the cavity and at least in a region adjacent to the said cavity. A thick layer of dielectric is deposited. A fourth hole is etched away in the thick layer of dielectric, so as to be in alignment with the hole filled with the second conductive material, until the said second conductive material is reached. The said fourth hole is filled with a third conductive material in order to form a via comprising the second, third and fourth holes filled with the first, second and third conductive materials.

The second and third materials are preferably different.

The subject of the invention is also a process for fabricating an integrated circuit comprising at least one capacitor placed above a substrate and at least one via for connection between the substrate and a conducting level lying above the capacitor, in which, starting from a substrate covered with at least one dielectric layer, a first hole and a second hole are simultaneously etched away and filled with a first electrically conductive material, a dielectric layer is deposited, the dielectric layer is etched away to produce at least one cavity above the first filled hole for the purpose of forming a capacitor and at least one third hole above the filled second hole for the purpose of forming a via, a layer of a second conductive material is deposited on the upper surface of the dielectric layer, the said material filling the said third hole and coating the walls of the said cavity, the said second conductive material is removed from the upper surface of the dielectric layer, at least one thin layer of dielectric is deposited at least on the surface of the said conducting layer in the said cavity, a second layer of the second conductive material is deposited at least in the cavity and in a region adjacent to the cavity, a thick layer of dielectric is deposited, a fourth hole is etched away in the said thick layer of dielectric, so as to be in alignment with the hole filled with the second conductive material, until the said second conductive material is reached, and the said fourth hole is filled with a third conductive material different to the second conductive material in order to form a via comprising the second, third and fourth holes filled with the first, secondhand third conductive materials.

The second layer of conductive material may be removed from the upper surface of the dielectric layer by etching and/or chemical mechanical polishing. The second layer of conductive material intended to form the second electrode may be deposited, locally or otherwise, on the integrated circuit during fabrication, and can then be subjected to a step in which it is partly removed by etching.

In one method of implementing the invention, when cutting out the third hole, the conductive material placed in the second hole is also etched away so as to remove it, and then these holes are filled with a conductive material. In this way, it is possible to have a conductive material whose properties are particularly well suited to a via.

The fact of having a local dielectric layer through which a metal via passes between an active region of the substrate and the first electrode of the capacitor allows the electrical resistance between these two elements to be reduced. The fact that the capacitor is separated from the substrate by a dielectric layer makes it possible to increase the integration density in the substrate, that is to say, in practice, to bring certain parts of the active regions of the substrate closer to the said via by at least partly placing them beneath at least one part of the electrodes of the capacitor.

Producing the via for connection to an upper level, for example a bit line in a DRAM cell matrix, in a number of steps, makes the fabrication easier by not having to produce a very long via in a single step, which causes substantial difficulties in filling the hole.

Some of the fabrication steps may be used to form other structures on the same wafer.

The capacitor may be formed by depositing a conducting layer, for example made of polysilicon, over the entire surface, local or otherwise, of the circuit being fabricated, that is to say on the upper surface of the dielectric layer in which the cavity and the hole have been formed, in the bottom of the cavities and on the sidewalls of the cavity. The via is formed simultaneously and from the same material as the first electrode, thereby not having to add further fabrication steps and therefore allowing a significant reduction in the fabrication time and the cost to be achieved.

The polysilicon of the upper surface of the dielectric layer is removed by an etching step or a chemical-mechanical polishing step. Next, one or more thin layers of a dielectric are deposited, again over the entire surface, local or otherwise, of the circuit being fabricated, that is to say on the first electrode formed by the polysilicon remaining in the cavity and on the upper surface of the dielectric layer in which the cavity is formed and on the upper surface of the via. A further polysilicon layer is then deposited, intended to form a second electrode, again over the entire surface of the integrated circuit.

The said polysilicon layer is removed, by a selective etching step, from part of the upper surface of the thick dielectric layer in which the cavity is formed, the latter already being covered by the thin dielectric layer or layers. It is thus possible to leave connections laying on the said thick dielectric layer. As a variant, the electrodes may be made of metal.

The present invention will be more clearly understood on studying the detailed description of one embodiment taken as an example, but in no way limiting, and illustrated by the appended drawings in which:

FIG. 1, already mentioned, is a schematic view of a memory cell;

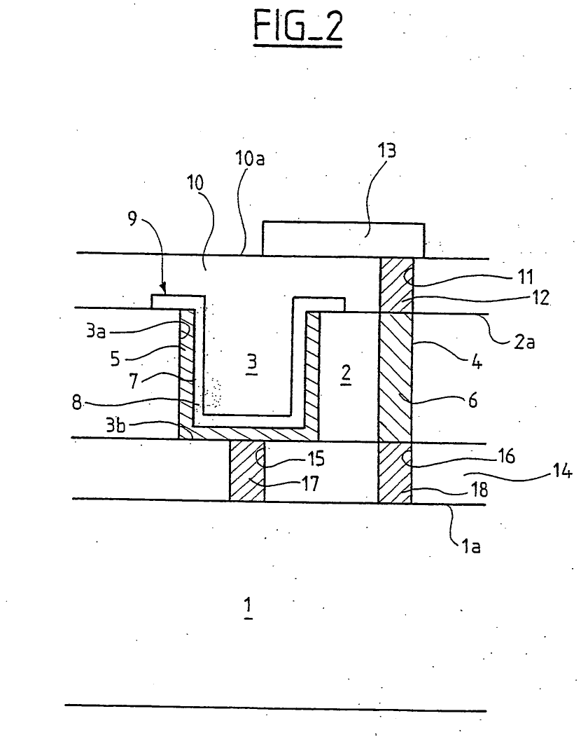

FIG. 2 is a schematic sectional view of an integrated circuit portion according to one aspect of the invention; and

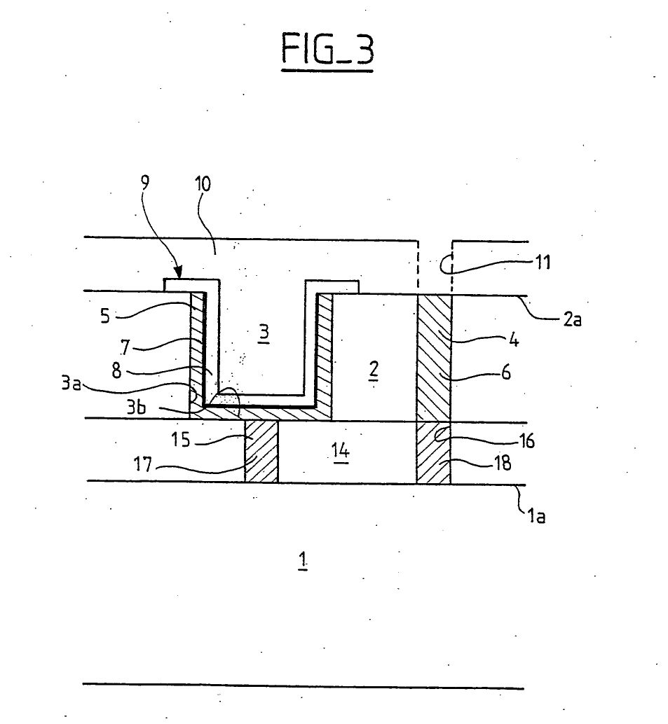

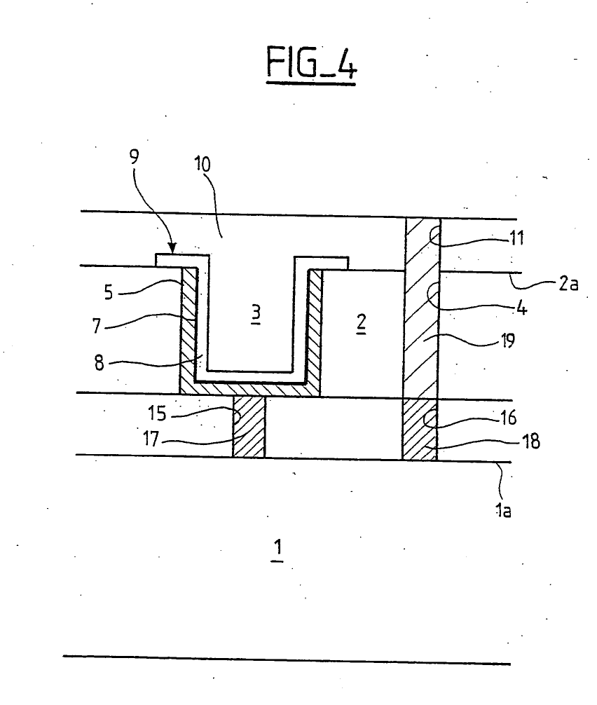

FIGS. 3 and 4 are schematic sectional views of an integrated circuit portion according to another aspect of the invention.

As may be seen in FIG. 2, an integrated circuit comprises a substrate 1 provided with an upper surface la on which active structures have been formed by ion implantation, these structures not having been shown in order to make the drawing clear.

After the active structures, for example one or more MOS transistors, have been formed, a low dielectric layer 14 having a thickness of between 0.05 and 0.5 m is deposited on the upper surface la of the substrate 1 and on the upper surface of the said active structures.

Two holes 15 and 16 are formed in the lower dielectric layer 14 by etching and are then filled with a first conductive material, for example metal or polysilicon, in order to form vias 17 and 18.

Next, an intermediate dielectric layer 2, which may be made of silicon oxide, silicon nitride, a glassy boron-phosphorus-silicon alloy (BPSG) or else a glassy phosphorus-silicon alloy (PSG), or made of any other material having suitable dielectric properties, is deposited on the dielectric layer 14.

Optionally, and not shown, a stop layer may be placed on the lower dielectric layer 14 before the intermediate dielectric layer 2 is deposited, in order to allow selective etching.

An etching step is then carried out, which makes it possible to open up, in the intermediate dielectric layer 2, a cavity 3 of relatively large dimensions, for example 0.4 μm×0.8 μm, the thickness of the lower dielectric layer 2 being between 0.5 and 1 μm, for example about 0.8 μm, and a third hole 4 of smaller dimensions. The hole 4 may have a width of about 0.5 to 3 μm, for example about 2 μm.

The cavity 3 is cut out so that it opens onto the upper surface of the via 17 and the hole 4 is formed so that it opens onto the upper surface of the via 18.

Next, a second conductive material, for example metal or more generally polysilicon, is deposited over the entire surface of the circuit, mainly on the upper surface 2a of the intermediate dielectric layer 2, on the bottom and on the sidewalls of the cavity 3 and in the hole 4. The thickness of the conducting layer thus formed is sufficient for it to completely fill the third hole 4 but not the cavity 3, only the edges 3a and the bottom 3b of which cavity are coated with the said layer.

Next, a step is carried out to remove the conducting layer from the upper surface 2a of the intermediate dielectric layer 2, by etching or else by chemical-mechanical polishing. At the end of this step, the upper surface 2a is exposed, whereas an electrode 5 with a U-shaped cross section has been formed in the cavity 3 and a via 6 completely filling the hole 4 has also been formed. The base of the via is in electrical contact with the upper part of the via 18. The upper surface of the via 6 is flush with the upper surface 2a of the intermediate dielectric layer 2. The height of the via 6 is approximately equal to the thickness of the dielectric layer 2.

Next, a thin dielectric layer is deposited over the entire surface of the circuit being fabricated. The thickness of this layer is such that it has been shown in FIG. 2 by a thickened line. The said dielectric layer covers the upper surface 2a, the upper surface of the via 6 and the free surfaces of the electrode 5. The dielectric 7 of the capacitor is thus formed during fabrication.

Next, a second conducting layer, for example made of metal or poly silicon, is deposited over the entire surface of the circuit being fabricated, that is to say on the thin dielectric layer. The said second dielectric layer is then partially removed, by etching, above at least part of the intermediate dielectric layer 2 and of the via 6. The second dielectric layer is left in the cavity 3 and along edges adjacent to the said cavity 3, in order thus to form a second electrode 8. In this way, a capacitor, integrated in its entirety by the reference number 9 and comprising a first electrode 5, a dielectric 7 and a second electrode 8, is formed.

Next, an upper dielectric layer 10 is deposited over the entire circuit being fabricated. The upper dielectric layer 10 fills the rest of the cavity 3 and has an approximately plane upper surface 10a. A fourth hole 11 is cut out from the upper surface 10a of the upper dielectric layer 10 by etching. The hole 11 is aligned with the via 6. The etching also makes it possible to remove the thin dielectric layer laying above the via 6 and reach the said via 6. Next, a conductive material, such as metal, is deposited in the hole 11 in order to form a via 12 which is flush with the upper surface 10a of the upper dielectric layer 10. It is then possible to form, on the upper surface 10a, a conducting level comprising at least one conducting track 13, made of metal, formed by a conventional process or else by a damascene process. The height of the via 12 is approximately equal to the thickness of the dielectric layer 10.

It will be understood that an electrical connection is provided between the substrate 1 and the conducting track 13 of an upper conducting level by means of three via portions 18, 6 and 12 each being relatively small in height, thereby ensuring that the holes 16, 4 and 11 have the correct geometry and that the said holes 16, 4 and 11 are properly filled with the conductive material forming the vias 18, 6 and 12, hence an excellent electrical contact is made. Furthermore, the step of forming the hole 4 and the via 6 is carried out at the same time as the step of forming the cavity 3 and the first electrode 5 of the capacitor 9 and is therefore carried out in parallel and for a constant cost. The step of forming the hole 11 and the via 12 is itself not only easier to carry out but also shorter because of their reduced height compared with a situation in which it would have been necessary to produce the holes 4 and 11 in a single etching step and the holes 6 and 12 in a single filling step.

This type of circuit makes it possible to increase the insulation between the capacitor 9 and the active regions of the substrate, or else to increase the integration density by placing some of the active regions of the substrate at least partly beneath part of the capacitor 9. Contact between the substrate 1 and the conducting track 13 is provided by a via made in three portions, each having a relatively small height and therefore allowing high precision in etching the holes and excellent filling with the conductive material.

FIG. 3 illustrates an embodiment similar to that in FIG. 2, except that when etching the hole 11 the said etching is continued by removing the via 6 from the hole 4. In other words, the etching is continued until the via 18 is reached. This allows the material making up the via 6, which is the same as that making up the first electrode 5 of the capacitor 9, to be replaced with a more suitable material having better electrical properties.

FIG. 4 shows that the etching has been continued until the via 18 is reached and that the hole 11 and the hole 4 thus exposed have then been filled with the single conductive material in order to form a via 19 whose height is approximately equal to the sum of the thickness of the dielectric layers 2 and 10. It is thus possible to use a conductive material having high electrical properties, while maintaining excellent geometry of the etching holes thanks to the prior etching of the hole 4.

As a variant, provision could also be made to expose only part of the hole 4 and to replace the via 6 only in part. In this regard, it is possible, for example, to replace the second material, making up the second portion 12 of the via, with another material, different from the first material making up the first portion 6 of the via, more suited to the envisaged use.

1-8. (Canceled)

9. An integrated circuit comprising:
a substrate;
at least one capacitor located above the substrate, the capacitor including a first electrode, a second electrode, and a capacitor dielectric between the first and second electrodes;
a conductor level located above the capacitor;
at least one via connecting the substrate and the conductor level; and
a dielectric covering the substrate and surrounding both the capacitor and the via, wherein the via includes:
a first portion extending from the substrate, the first portion having an upper surface at a level that is substantially the same as a lower level of the first electrode,
a second portion extending from the upper surface of the first portion, the second portion having an upper surface at a level that is substantially the same as an upper level of the first electrode, and
a third portion extending from the upper surface of the second portion, the third portion having an upper surface that is substantially flush with the conductor level, and
the second portion of the via and the first electrode of the capacitor are formed of the same material.

10. The integrated circuit according to claim 9, wherein the material of the second portion of the via and the first electrode of the capacitor comprises polysilicon.

11. The integrated circuit according to claim 9, wherein the material of the second portion of the via and the first electrode of the capacitor comprises metal.

12. The integrated circuit according to claim 9, wherein the material of the second portion of the via and the first electrode of the capacitor comprises a metal or a metal-based alloy, comprising at least one of copper, aluminum, tungsten, titanium and gold.

13. A method for fabricating an integrated circuit, said method comprising the steps of:
providing a substrate covered with at least a first dielectric layer; and
forming a first capacitor electrode that is located above the substrate, a capacitor dielectric, a second capacitor electrode such that the capacitor dielectric is located between the first and second capacitor electrodes, at least one via for connecting the substrate and a conducting level that is located above the capacitor, and a dielectric covering the substrate and surrounding both the capacitor and the via,
wherein the via includes:
a first portion extending from the substrate, the first portion having an upper surface at a level that is substantially the same as a lower level of the first electrode,
a second portion extending from the upper surface of the first portion, the second portion having an upper surface at a level that is substantially the same as an upper level of the first electrode, and
a third portion extending from the upper surface of the second portion, the third portion having an upper surface that is substantially flush with the conductor level, and
the second portion of the via and the first electrode of the capacitor are formed of the same material.

14. The method according to claim 13, wherein the forming step includes the sub-steps of:
simultaneously etching a first hole and a second hole;
filling the first and second holes with a first electrically conductive material;
depositing a dielectric layer;
etching the dielectric layer so as to produce at least one cavity above the first hole for forming a capacitor, and to produce at least one third hole above the second hole for forming the via;
depositing a layer of a second conductive material on the upper surface of the dielectric layer such that the second conductive material fills the third hole and coats the walls of the cavity;
removing the second conductive material from the upper surface of the dielectric layer;
depositing at least one thin layer of dielectric at least on the surface of the second conducting layer in the cavity;
depositing a second layer of the second conductive material at least in the cavity;
depositing a thick layer of dielectric;
etching a fourth hole in the thick layer of dielectric so as to be in alignment with the third hole, the etching continuing until the second conductive material filling the third hole is reached; and
filling the fourth hole with a third conductive material in order to form the via comprising the second, third and fourth holes filled with the first, second and third conductive materials.

15. The method according to claim 14, wherein the second and third materials are different.

16. The method according to claim 14, wherein the second conductive material comprises polysilicon.

17. The method according to claim 14, wherein the second conductive material comprises metal.

18. The method according to claim 14, wherein the second conductive material comprises a metal or a metal-based alloy, comprising at least one of copper, aluminum, tungsten, titanium and gold.

19. A method for fabricating an integrated circuit comprising at least one capacitor located above a substrate and at least one via connecting the substrate and a conductor level that is located above the capacitor, said method comprising the steps of:
providing a substrate covered with at least a first dielectric layer;
simultaneously etching a first hole and a second hole;
filling the first and second holes with a first electrically conductive material;
depositing a dielectric layer;
etching the dielectric layer so as to produce at least one cavity above the first hole for forming a capacitor, and to produce at least one third hole above the second hole for forming the via;
depositing a layer of a second conductive material on the upper surface of the dielectric layer such that the second conductive material fills the third hole and coats the walls of the cavity;
removing the second conductive material from the upper surface of the dielectric layer;
depositing at least one thin layer of dielectric at least on the surface of the second conducting layer in the cavity;
depositing a second layer of the second conductive material at least in the cavity; depositing a thick layer of dielectric;
etching a fourth hole in the thick layer of dielectric so as to be in alignment with the third hole, the etching continuing until the second conductive material filling the third hole is reached; and
filling the fourth hole with a third conductive material in order to form the via comprising the second, third and fourth holes filled with the first, second and third conductive materials.

20. The method according to claim 19, wherein the second and third materials are different.

21. The method according to claim 19, wherein the second conductive material comprises polysilicon.

22. The method according to claim 19, wherein the second conductive material comprises metal.

23. The method according to claim 19, wherein the second conductive material comprises a metal or a metal-based alloy, comprising at least one of copper, aluminum, tungsten, titanium and gold.
